(19) United States
(12) Patent Application Publication
(10) Pub. No.: US 2026/0190257 A1
(43) Pub. Date: Jul. 2, 2026

(54) RISER CARD BRACKET

(71) Applicant: Aivres Systems Inc., San Jose, CA (US)

(72) Inventor: Heng LU, New Taipei City (TW)

(21) Appl. No.: 19/003,409

(22) Filed: Dec. 27, 2024

(51) Int. Cl. H05K 5/02; G06F 1/185; G06F 1/186; H05K 7/14; H05K 7/20

(52) U.S. Cl. CPC H05K 5/023; G06F 1/185; G06F 1/186; H05K 7/1405; H05K 7/1407; H05K 7/20272

(57) ABSTRACT

A riser card bracket installs and braces an expansion card to an expansion socket slot inside the chassis of a computing system. The riser card bracket is attached along an upper card edge of the expansion card prior to assembly inside the chassis. The riser card bracket includes a first lever handle having a first camming structure and that is pivotally attached to a first end of a card beam and a second lever handle having a second camming structure that is pivotally attached to the second end of the card beam. Pivoting the first and second lever handles with respect to the card beam causes the first and second camming structures to forcibly engage respective first and second catches located within the chassis.

### TECHNICAL FIELD

This patent application relates to components for computing systems, in particular, to a bracket structure for electrically and mechanically connecting the internal computer devices and components together.

### BACKGROUND

Many computer systems, and particularly servers communicatively connected to a computer network to provide functionality and resources for other systems, are modularly designed for flexibility and scalability. For example, various computer components can be added or swapped to improve or change the functionality and capabilities of the computer system. A common design for modular computer systems is to include one or more expansion sockets located on a printed circuit board such as the motherboard or a dedicated expansion board accommodated internally inside a system chassis or server chassis. To modify or improve the computer system, additional circuit boards with the appropriate electronic components mounted thereon can be inserted and electrically connected to the connector sockets to communicate and interact with the computer components previously included with the computer system. The new combination expands the functionality of the computer system.

The added circuit boards are typically configured as planar printed circuit cards referred to as expansion cards or riser cards, and the expansion sockets are configured as elongated slots to receive an edge of the expansion card. Riser cards, for example, are often oriented vertically so the cards can be placed into the connector sockets in an upright configuration, perpendicular to a horizontally positioned expansion board or motherboard.

To support the expansion cards that are received in the expansion slots or sockets, support structures can be included that mechanically attach the expansion cards to the expansion boards. The mechanical support structures may involve threaded fasteners, which complicates assembly due to the spatial constraints inside the chassis. Further, in some embodiments, the expansion cards may include different connection configurations that require the cards to be forcibly inserted into the expansion slots to establish a secure connection.

### SUMMARY OF THE DISCLOSURE

To install an expansion card into an expansion socket slot in a computer system, the disclosure provides a riser card bracket that can attach to the expansion card and can engage with corresponding structures fixedly located in the chassis. In particular, the riser card bracket can include an elongated card beam that is joined to and extends along an upper card edge of the expansion card. The riser card bracket also includes a first lever handle that is pivotally attached by a first fulcrum to a first beam end of the elongated card beam and a second lever handle that is pivotally attached by a second fulcrum to a second beam end located opposite of the first beam end.

The first and second lever handles can each respectively include first and second camming structures that are situated to project outwardly from the first and second beam ends. When the expansion card is aligned with the expansion socket slot, the first and second lever handles are pivotally rotated with respect to the elongated card beam to engage with corresponding first and second catches fixedly located in the chassis. The first and second camming structures forcibly inserts the expansion card into electrical contact with the expansion card slot and may simultaneously engage other mating features, such as a fluid supply manifold for liquid cooling.

The disclosure also provides a method of installing an expansion card into a computer server using the riser card bracket. The riser card bracket can be attached to the expansion card prior to installation into the computer system, and may be pre-assembled as a riser card assembly. When the riser card assembly is aligned with the expansion socket slot and, if included, with the manifold ports of a fluid supply manifold, the first and second lever handles are pivotally rotated with respect to the card beam to move the first and second camming structures at the opposite ends of the card beam into engagement with respective first and second catches at fixed locations within the chassis. Actuating the first and second lever handles simultaneously moves the riser card assembly uniformly into contact with the expansion socket slot and the fluid supply manifold, avoiding misalignment or disrupted connections.

The disclosure also provides a computer system, such as a server, that can be modified or functionally scaled by the inclusion of one or more expansion cards. The server includes a chassis defining an internal chassis volume. Located in the chassis volume can be one or more expansion socket slots that may be parallel and a fluid supply manifold orthogonal to the expansion socket slots. A riser card assembly can be plugged into one of the expansion socket slots through actuation of a riser card bracket. For example, the riser card bracket may include a card beam extending along an upper edge of the expansion card and may further include first and second lever handles that are pivotally joined to opposite first and second beam ends by respective first and second fulcrums. The first lever handle includes a first camming structure that forcibly engages a first catch located in the chassis and the second lever handle includes a second camming structure that forcibly engages a second catch. The riser card assembly is therefore uniformly moved into contact with the expansion card slot and the fluid supply manifold.

A possible advantage of the disclosed riser card bracket is that a mechanical advantage is obtained through pivotal actuation of the first and second lever handles to install the expansion card with the expansion card socket and, if included, the fluid supply manifold. In particular, the dimensional differences between the swinging first and second free ends of the first and second lever handles and the respective pivotal fulcrums amplifies the forces applied at the camming structures. Forcible interaction between the first and second camming structures and the respective first and second, fixedly located catches, applies an increased force in the downward vertical direction to connect the expansion card with the expansion socket slot and the fluid supply manifold.

A related possible advantage is that the riser card assembly is moved uniformly in the vertical direction by simultaneous actuation of the first and second lever handles to simultaneously connect with the expansion socket slot and the fluid supply manifold, which avoids possible tilting and misalignment in the longitudinal direction. Another possible advantage is that the riser card bracket can be attached to the expansion card prior to assembly into the computer system. Pre-assembly facilitates subsequent installation of the expansion card into the chassis, in which space may be limited or crowded, or access may be restricted.

### BRIEF DESCRIPTION OF THE DRAWINGS

FIG. 1 is a perspective view of a computer system having a system chassis accommodating computer components including expansion cards, fan modules, and processing units.

FIG. 2 is perspective view of a portion of the system chassis illustrating an expansion card installed and braced to an expansion board and to a fluid supply manifold by a riser card bracket.

FIG. 3 is a perspective view of the riser card bracket having an elongated card beam for engaging the riser card and a first lever handle and a second lever handle pivoted apart from the card beam.

FIG. 4 is a perspective view of the card beam extending in a longitudinal direction between a first beam end and a second beam end.

FIG. 5 is a perspective view of the first lever handle having first fulcrum located between a first free end and a first camming structure configured as a camming prong.

FIG. 6 is a perspective view of the second lever handle having a second fulcrum located between a second free end and a second camming structure configured as bifurcated camming jaws.

FIG. 7 is a perspective view of the riser card bracket with the first and second lever handles pivoted apart from the card beam and a bridge connector connecting with the card beam.

FIG. 8 is a perspective view of the riser card bracket attached to the upper card edge of the expansion card to produce a riser card assembly.

FIG. 9 is an elevational view of the riser card assembly aligned with the expansion board and the fluid supply manifold with detailed views of the first camming mechanism and the second camming mechanism.

FIG. 10 is a detailed view of an example of the first biasing spring which may be embodied as a helical coil spring.

FIG. 11 is a detailed view of an example of the second biasing spring which may be embodied as a torsion spring.

FIG. 12 is an elevational view of the riser card assembly connected to the expansion board and to the fluid supply manifold with the first camming mechanism and the second camming mechanism each in the locked configuration.

### DETAILED DESCRIPTION

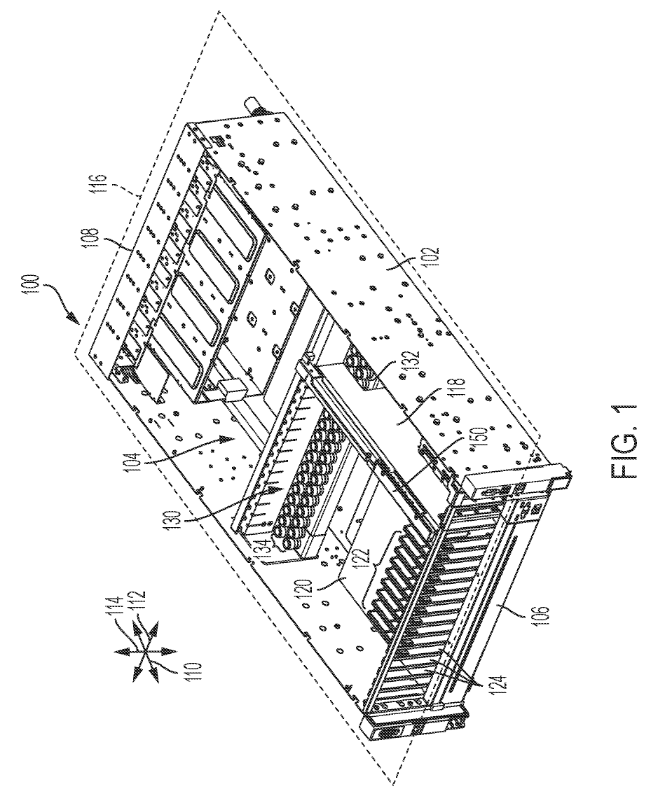

Now referring to the drawings, where whenever possible like reference numbers will refer to like elements, there is illustrated in FIG. 1 a computer system 100 comprised of various electronic devices and hardware that are cooperatively interconnected and assembled together and that may be accommodated in a common chassis 102. The chassis 102 can be a box-like structure made of formed sheet metal or molded plastic and that defines an internal space or chassis volume 104 for the internal computer components and electronic hardware of the computer system 100. The computer system 100 can be configured for communicative integration with a larger network or system and the chassis 102 may be designed for mounting into a rack with similar computer systems, although in other instances the computer system 100 may be a standalone configuration.

The chassis 102 can accommodate components and hardware devices like central processing units, memory modules, hard drives, power convertors, and fan units for circulating air internally about the chassis volume 104 for cooling of the internal components. The box-like chassis 102 may be rectangular in shape and can extend between a front panel 106 and rear panel 108 that are parallel to each other and located opposite one another with respect to longitudinal direction 110 of the computer system 100. The front and rear panels 106, 108 can include various LED indicator lights, activation and setting buttons and switches, ports and sockets for data and power communications, and other features for interfacing with operators and other systems. In addition to the longitudinal direction 110, the chassis 102 can define and be oriented in reference to a lateral direction 112 that defines the width of the computer system 100 and a vertical direction 114 that perpendicularly intersects the longitudinal and lateral directions 110, 112. The longitudinal direction 110 and the lateral direction 112 may interact at perpendicular angles and define a horizontal plane 116 for reference purposes.

To expand the functionality of the computer system 100, one or more expansion cards 118 can be selectively included when desired, and can be internally accommodated in the chassis volume 104. The expansion cards 118, also referred to as PC cards, adapter cards, extension cards, and the like, may be planar circuit boards shaped and sized as quadrilateral cards having additional electronic devices mounted thereon. The mounted devices may be integrated circuits such as memory expansion modules, specialized processing units, communications and interface circuits, etc. In a specific example, the expansion card 118 can include one more graphics processing units (GPUs) that are designed for applications such as image processing, data analytics, artificial intelligence, and other high-performance computing applications.

To connect with the expansion cards 118, the computer system 100 can include an expansion board 120 located in the chassis volume 104 and fixed to the chassis 102. The expansion board 120 can also be a planar printed circuit board spatially supported parallel to the horizontal plane 116. The expansion board 120 can include a plurality of connector socket slots 122 into which the expansion cards 118 may be plugged. The connector socket slots 122 are configured as elongated slots aligned with the longitudinal direction 110. The expansion cards 118 can be inserted into the connector socket slots 122, which may include spring loaded contacts that bias against corresponding conductive traces on the surfaces of the expansion card to established electronic communication between the components.

The plurality of elongated expansion socket slots 122 can be arranged in parallel to each other and laterally distributed in the lateral direction 112. To access the expansion cards 118, the chassis 102 can include a plurality of expansion bays 124 that are formed as openings in the forward panel 106 for example. The expansion bays 124 can be arranged along the lateral direction 112 and correspondingly aligned with respective expansion socket slots 122 on the expansion board 120. The openings associated with the expansion bays 124 enable the expansion cards 118 to form electrical connections with external cables, plugs, and the like. In the described arrangement, the expansion board 120 is located adjacent to the forward panel 106 of the chassis 102, although other spatial configurations and arrangements are possible.

In an embodiment, the expansion cards 118 can be designed to functionally interface with other subsystems and internal components of the computer system 100 in addition to the expansion board 120. For example, if the expansion card 118 is configured as a graphics processing unit (“GPU”) or similar device, the electronic components mounted thereon may require additional cooling. The computer system 100 can be equipped with a fluid cooling system that includes a fluid supply manifold 130 configured to deliver a fluid such as cooling water to the plurality of expansion cards 118. The fluid supply manifold 130 can be part of a fluid circuit that circulates cooling water to the various internal components of the computer system 100 as part of a thermal management system.

The fluid supply manifold 130 can include a manifold block 132 that has an elongated shape and that is located in the chassis volume 104 aligned parallel to the lateral direction 112. The manifold block 132 can be located rearward, in the longitudinal direction 110, of the expansion board 120 that is adjacent to the rear panel 108. The laterally directed manifold block 132 therefore extends orthogonally across the plurality of expansion cards 118 that may be installed in the expansion socket slots 122 of the expansion board 120. The fluid supply manifold 130 can also include a plurality of manifold ports 134 that project upright from the manifold block 132 in the vertical direction 114 to connect with corresponding features on the expansion card 118.

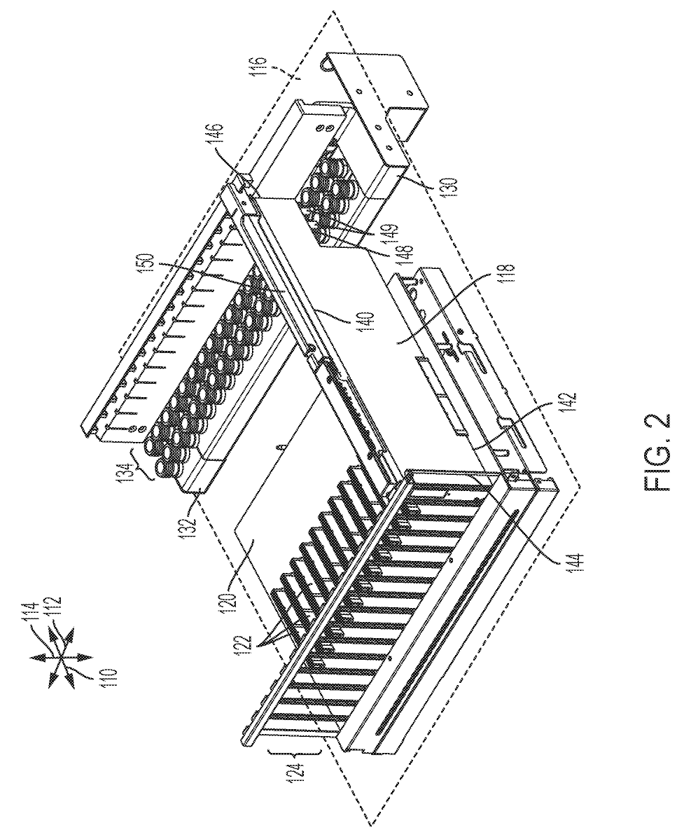

Referring to FIG. 2, the expansion cards 118 can have a rectangular planar configuration including an upper card edge 140 and a parallel lower card edge 142 that is adapted to be inserted into the expansion socket slots 122 on the expansion board 120. The lower card edge 142 can be configured as an edge connector and may include a plurality of conductive traces that are exposed thereon to make electrical contact with corresponding conductive springs-loaded contacts in the connector socket slots 122 when the expansion board 120 is inserted and installed thereon. When the expansion board 118 is installed in the chassis 102, the upper and lower card edges 140, 142 are aligned parallel with the longitudinal direction 110 of the computer system 100. The expansion card 118 can include a forward card edge 144 and a parallel rearward card edge 146 that are orthogonal to the upper and lower card edges 140, 142 and that may be aligned in the vertical direction 114. When the expansion card 118 is assembled, the forward card edge 144 may be situated adjacently with respect to the expansion bay 124 of the front panel 106.

If the computer system 120 includes a fluid supply manifold 130, the expansion card 118 might include a recessed card edge 148 adapted to fit about the manifold block 132. The recessed card edge 148 can be located perpendicular to the rearward card edge 146 and parallel to and vertically spaced from the lower card edge 142 to produce a notch in the expansion board 118. When the expansion card 118 is connected to the expansion board 120, the notch associated with the recessed card edge 148 aligns with and receives the manifold block 132. To fluidly connect with the manifold ports 134 on the fluid supply manifold, the expansion card 118 can include one or more corresponding fluid ports 149 projecting downwardly in the vertical direction 114 from the recessed card edge 148. In the illustrated example, two fluid ports 149 can be included on the expansion card 118 to intake and discharge cooling water as appropriate.

To facilitate connecting the expansion card 118 to the expansion board 120 in a secure manner, each expansion card can be operatively associated with a riser card bracket 150. The riser card bracket 150 can be adapted to align the expansion card 118 upright in the vertical direction 114 and longitudinally with respect to the expansion socket slot 122. Moreover, the riser card bracket 150 can be a mechanical system that is adapted to apply a positive installation force along the upper card edge 140 of the expansion card 118 forcing the parallel lower card edge 142 into expansion socket slot 122. Specifically, actuation of the riser card bracket 150 creates an installation force in the vertical direction 114 that inserts and forcibly plugs the expansion card into electrical connection with the respective expansion socket slot 122.

If the computer system 100 includes a fluid supply manifold 130, the installation force produced by actuation of the riser card bracket 150 can simultaneously and forcibly connect the fluid ports 149 located along the recessed card edge 148 to the manifold port 134 on the manifold bock 132. To prevent unintentional disconnection of the expansion card 118, the riser card bracket 150 can include a locking mechanism that fixedly locks the expansion card in the chassis volume 106 with respect to the expansion socket slot 122. To remove the expansion card 118 from the computer system 100, the locking mechanism of the riser card bracket 150 can be selectively released.

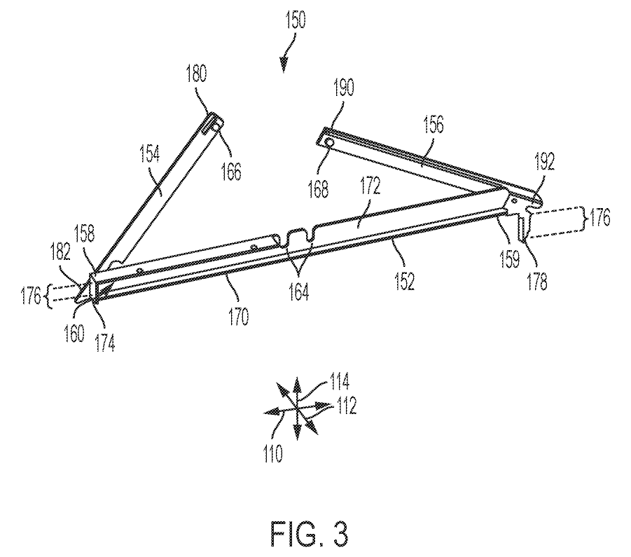

Referring to FIG. 3, the riser card bracket 150 can be assembled from rigid structural components including an elongated card beam 152 that is movably connected with a first lever handle 154 and a second lever handle 156. For rigidity and strength, the card beam 152 and the first and second lever handles 154, 156 can be made of structural sheet steel that is pressed and formed into the desired shapes. In use, the elongated card beam 152 can be adapted to attach to the upper card edge of the expansion card and may therefore aligned with the longitudinal direction 110. The elongated card beam 152 can include a first beam end 158 and a longitudinally opposite second beam end 159. When assembled, the first lever handle 154 connects proximately to the first beam end 158 and the second lever handle 156 connects proximately to the second beam end 159.

To actuate the riser card bracket 150, the first lever handle 154 can be pivotally connected to the first beam end 158 of the card beam 152 by a first fulcrum 160 and the second lever handle 156 can be similarly connected to the second beam end 159 by a second fulcrum 162. The pivotal connections associated with the first and second fulcrums 160, 162 can include rivets or pins that allow the first and second lever handles 154, 156 to rotate with respect to the elongated card beam 152. For example, the first and second lever handles 154, 156 can rotate from alignments that are parallel in the longitudinal direction 110 to the elongated card beam 152 to vertically pivot apart from the card beam 152.

To lock and hold the first and second lever handles 154, 156 parallel with the elongated card beam 152, first and second locking slots 164 can be structurally formed into the card beam. The first and second locking slots 164 are adapted to snap with a first locking knob 166 on the first lever handle 154 and with a second locking knob 168 on the second lever handle 156. The pair of locking slots 164 and the corresponding first and second locking knobs 166, 168 cooperate to produce the locking mechanism that can securely brace the expansion card to the expansion sockets slots as described above.

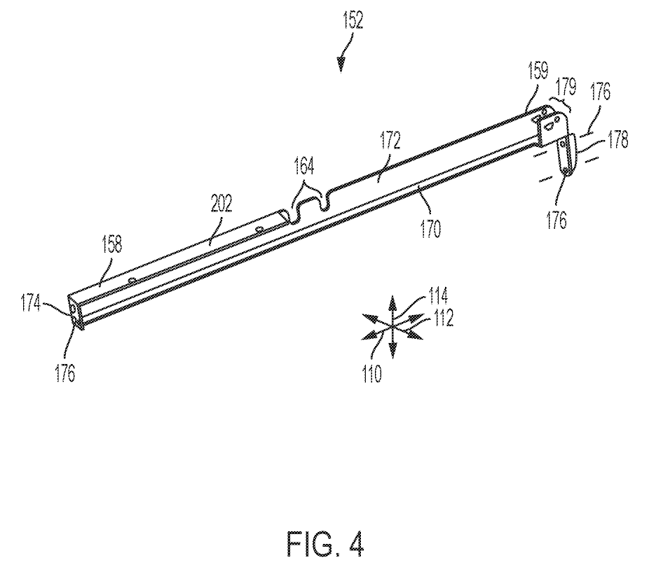

Referring to FIG. 4, the elongated card beam 152 can be shaped as a structural angle having two orthogonally intersecting beam flanges 170, 172 extending together in the longitudinal direction 110 between the oppositely located first beam end 158 and the second beam end 159. The horizontal beam flange 170 can be adapted to extending adjacent to the upper edge of the expansion card and the vertical beam flange 172 may be oriented in the vertical direction 114 when the riser card bracket is attached to the expansion card. The first and second locking slots 164 can be located mid-length in the vertical beam flange 172 of the card beam 152. To extend coextensively with the expansion card when attached, the longitudinal dimension of the elongated card beam 152 between the first beam end 158 and the second beam end 159 can correspond with the length of the expansion card in the longitudinal direction 110.

To attach the riser card bracket with the expansion card, the first beam end 158 can include a lateral face 174 that is perpendicular to the longitudinal direction 110 and can be configured to make abutting contact with a respective one of the forward or rearward card edges of the expansion card. Disposed into the lateral face 174 in the longitudinal direction 110 can be one or more fastener apertures 176 that are each adapted to receive a threaded fastener. The second beam end 159 can include an extension leg 178 that extends in the vertical direction 114 and perpendicular to the longitudinal direction 110. The extension leg 178 can be adapted to slidingly abut against an opposite forward or rearward card edge of the expansion card when the card beam 152 is attached thereto. Located in the extension leg 178 can be one or more additional fastener apertures 176 that are adapted to receive and align threaded fasteners in the longitudinal direction 110. To assist attaching the elongated card beam 152 with the second lever arm 156, the second beam end 159 can be shaped as a structural channel formed by parallel upright walls 179 aligned in the longitudinal direction 110 and forming a gap there between.

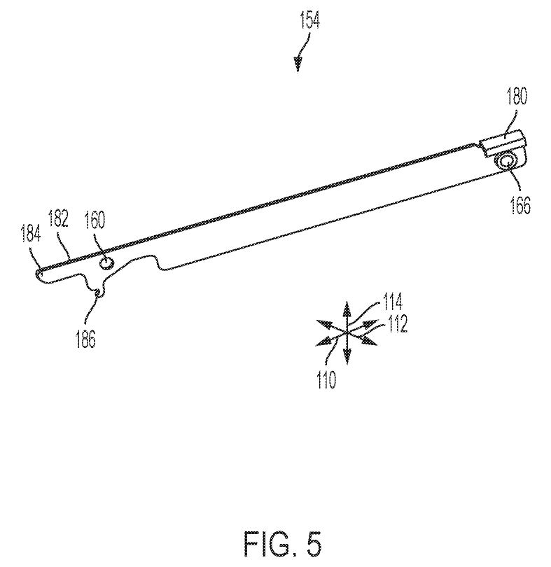

Referring to FIG. 5, in an example, the first lever handle 154 can be made of sheet steel pressed and formed as an elongated bar-shape structure enabling the first lever handle to pivotally rotate with respect to the first fulcrum 160, which may be structurally configured as a hole or aperture to receive a pin or rivet. For example, the first lever handle 154 can extend between a first free end 180 and a first camming structure 182 that are oppositely located with respect to the first fulcrum 160. Dimensionally, the length of the first lever handle 154 between the first free end 180 and the first camming structure 182 may be approximately half the longitudinal dimension of the card beam in FIG. 3. The first locking knob 166 can be connected to the first free end 180 by fasteners or rivets to project in the lateral direction 112.

The first fulcrum 160 may be shifted longitudinally in proximity toward to first camming structure 182 so that the first free end 180 has a substantial length relative to the comparative length of first camming structure 182 opposite the first fulcrum 160. The first lever handle 154 is thereby enabled to apply leverage to the first camming structure 182 when pivoted about the first fulcrum 160. To concentrate and output the applied leverage, the first camming structure 182 can include a camming prong 184 that may be aligned with and configured as a narrower continuation of the extension of the first lever handle 154. The camming prong 184 can be single finger or digit shaped to engage or pry an appropriate catch.

In a possible configuration, the first lever handle 154 can include a spring hook 186 that extends vertically downward from the first camming structure 182 in the vertical direction 114 and that is located forwardly of the first fulcrum 160. The spring hook 186 can include a curve or bend at the distal end of the vertically downward extending shank that can engage a spring, as described below.

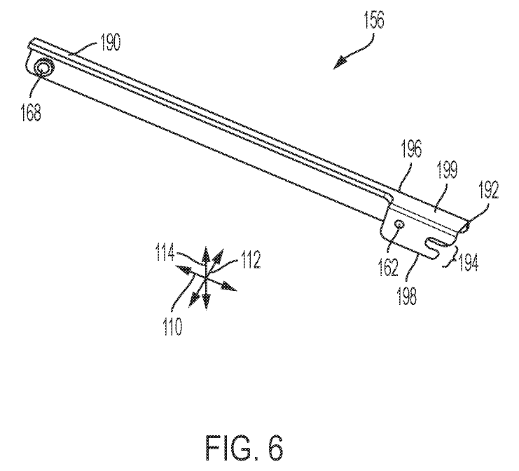

Referring to FIG. 6, in an example, the second lever handle 156 can be made of pressed and formed sheet steel shaped as another elongated bar extending between a second free end 190 and a second camming structure 192 oppositely located with respect to the second fulcrum 162. The length of the second lever handle 156 can also be approximately half of the comparative longitudinal length of the card beam. The second locking knob 168 can be fastened to the second free end 190 to project in the lateral direction 112.

To generate leverage, the length of the second free end 190 as measured from the second fulcrum 162 can be substantially longer than the comparative length of the second camming structure 192. The second camming structure 192 can be configured as a camming jaw 194 having bifurcated fingers or prongs that are separated and spaced apart to define a slot or opening that can receive and engage an appropriate catch. The camming jaw 194 and the opening defined by the bifurcated structure may be generally aligned with reference to the longitudinal direction 110 when the second lever handle 154 is appropriately pivoted.

The second lever handle 156, in an example, can be shaped in part as a three-sided structural channel referred to as an end channel 196 that partially corresponds with the second camming structure 192. The three-sided end channel 196 may include two vertical channel flanges 198 that align with the vertical direction 114 and a web 199 that extends horizontally between the two vertical channel flanges 198. The camming jaws 194 can be formed in the two vertical channel flanges 198.

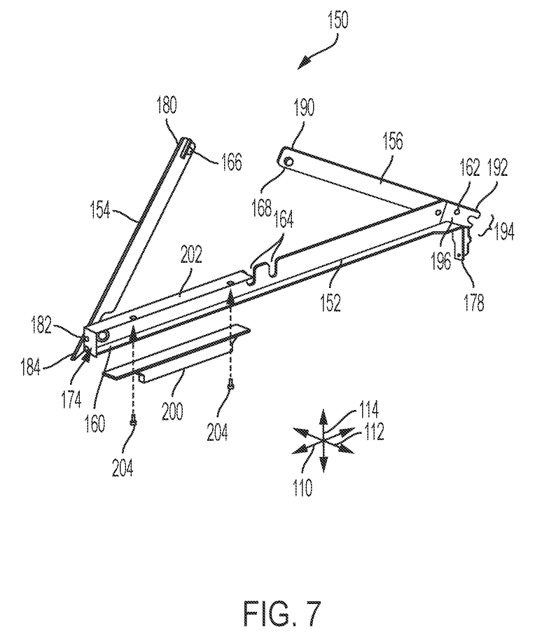

Referring to FIG. 7, to prepare the riser card bracket 150 for attachment, the first lever handle 154 can be pivotally attached to the first beam end 158 of the elongated card beam 152 via the first fulcrum 160 and the second lever handle 156 can be pivotally attached to the second beam end 159 of the elongated card beam 152 via the second fulcrum 162. The pivotal connections enabled by the first and second fulcrum 160, 162 allow the first and second free ends 180, 190 to be pivoted away and swung upward from the elongated card beam 152, which may be aligned with the longitudinal direction 110, as shown. The first and second free ends 180, 190 may be normally biased apart from the elongated card beam 152 as explained further below. The first lever handle 154 and the second lever handle 156 are angularly oriented with respect to the elongated card beam 152 aligned with the longitudinal axis 110 in what may be referred to as a released configuration or arrangement.

When the first lever handle 154 is connected to the elongated card beam 152 by the first fulcrum 160, the first camming structure 182 can extend beyond the physical extension of the first beam end 158. Likewise, when the second lever handle 156 is connected to the elongated card beam 152 by the second fulcrum 162, the second camming structure 192 can extend beyond the physical extension of the second beam end 159. The first and second camming structures 182, 192 are physically unencumbered to engage with corresponding structures to secure the expansion card.

To provide additional electrical connectivity with the expansion card, the riser card bracket 150 can be operatively associated with a bridge connector 200. The bridge connector 200 can be an elongated edge connector or edge socket accommodating a plurality of conductive contacts or pins that can establish electrical communication with the expansion card. The bridge connector can be attached to the elongated card beam 152 to align with the longitudinal direction 110. To facilitate attachment, the elongated card beam 152 can include a horizontal connector flange 202 or similar structure that is disposed in the lateral direction 112 and that is integrally joined to one half of the elongated card beam, for example, between the first beam end 158 and the first and second locking slots 164 located mid-length of the card beam.

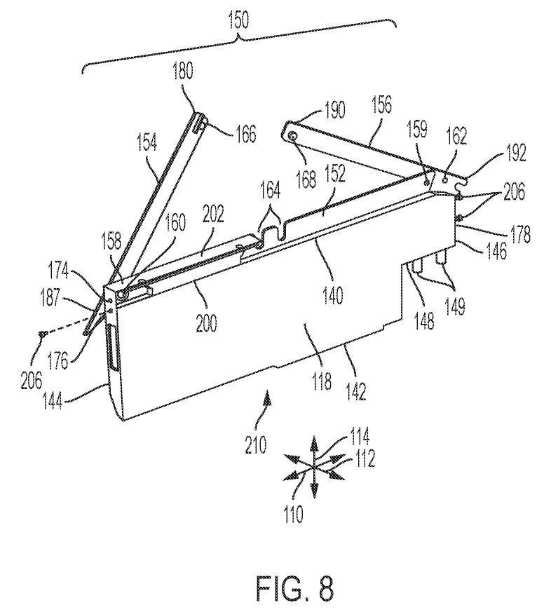

Referring to FIG. 8, to attach the riser card bracket 150 to the expansion card 118, the elongated card beam 152 can be aligned with the linear upper card edge 140 in common respect to the longitudinal direction 110. Preferably, the longitudinal dimension between the first beam end 158 and the second beam end 159 corresponds with the length of the expansion card 118 such that the card beam 152 is coextensive with the upper card edge 140. The lateral face 174 located at the first beam end 158 can be adjacently disposed and abut against the forward card edge 144 and the extension leg 178 located at the second beam end 158 can adjacently slide against the rearward card edge 146.

The upper card edge 140 extending between the forward and rearward card edges 140, 142 is therefore constrained between the lateral face 174 and the extension leg 178 with respect to the longitudinal direction 110. The first and second camming structure 182, 192, however, may physically extend beyond the forward and rearward card edges 144, 146 respectively, although at an angle with respect to the longitudinal direction 110. Furthermore, the bridge connector 200 can be align with the upper card edge 140 in the longitudinal direction 110 and can be electrically connected with suitable conductors located thereon.

To fix the riser card bracket 150 to the expansion card 118, threaded fasteners 206 can be inserted through the fastener apertures 176 disposed in the lateral face 174 adjacent the forward card edge 144 and the extension leg 178 adjacent the rearward card edge 146. The fasteners 206 may thread into appropriate holes in the forward and rearward card edges 144, 146 or may be self-tapping. The combination of the expansion card 118 and the fixedly attached riser card bracket 150 may be referred to as riser card assembly 210 and can be assembled prior to and in advance of installation into the computer assembly.

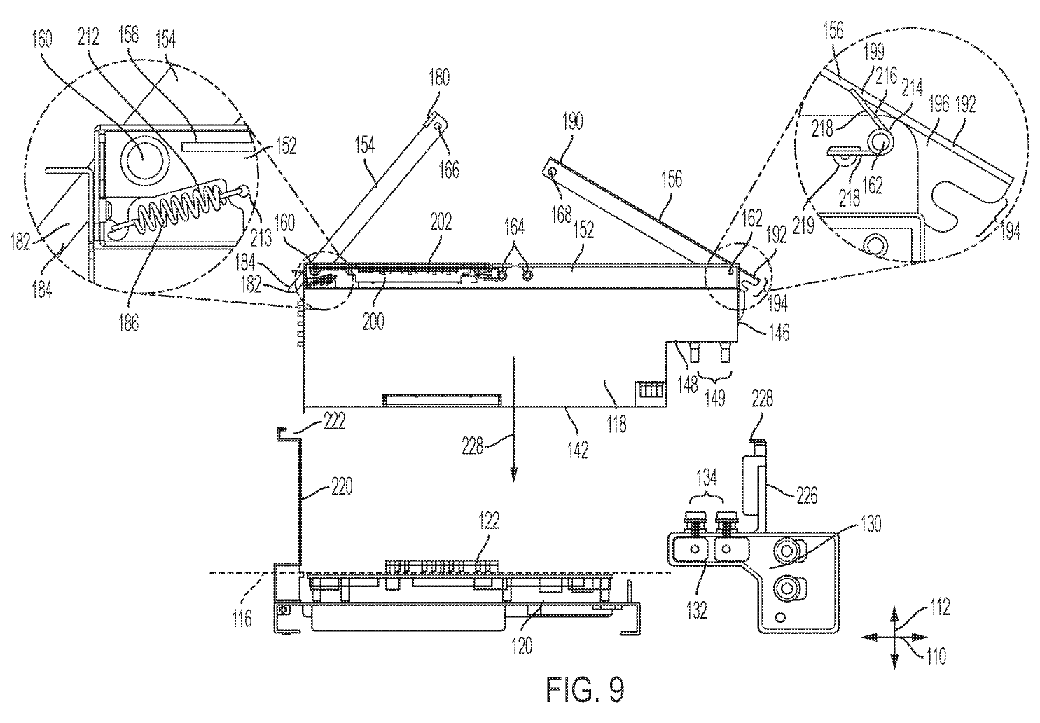

Referring to FIG. 9, to connect with the expansion board 120, the riser card assembly 210 is positioned vertically above the expansion board so that the lower card edge 142 aligns with the expansion socket slot 122 in the longitudinal direction 110. The first and second lever handles 145, 156 can rotate about the first and second fulcrums 160, 162 respectively to pivot apart from the elongated card beam 152 aligned in the longitudinal direction 110 so that the riser card bracket 150 is in the released arrangement. To maintain the riser card assembly 210 in the released arrangement, one or more biasing springs can be included that bias the first lever handle 154 and the second lever handle 156 apart from the elongated card beam 152.

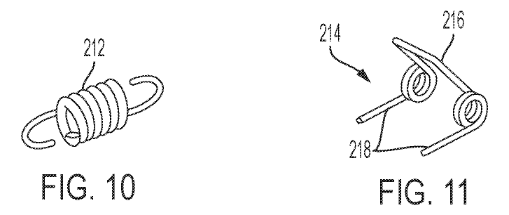

For example, referring to FIG. 10, a first biasing spring 212 can be operatively disposed in connection with the first beam end 158 and the first lever handle 154 to tilt the first free end 180 upwards and apart from the elongated card beam 152. In an embodiment, the first biasing spring 212 can be a helical coil spring that stretches in tension and retracts in compression. As shown in detail, the first biasing spring 212 can be connected at one end to the first beam end 158 and at the other end to the first lever handle 154. For example, the first biasing spring 212 may connect to the spring hook 186 located proximate to the first camming structure 182 and offset from the first fulcrum 160 and can be connected to an aperture or opening in the first beam end 158 of the card beam 152 located on oppositely of the first fulcrum 160. To secure with the first biasing spring 212, a spring aperture 213 or similar feature can be located in the first beam end 158. The first coil spring 212 thus spans the first fulcrum and can be configured pull the spring hook 186 toward the first beam end 158, thereby tiling the first free end 180 with respect to the card beam.

Referring to FIG. 11, the second biasing spring 214 can be operatively disposed in connection with the second beam end 159 and the second lever handle 156 to tilt the second free end 190 upwards and away from the elongated card beam 152. In an embodiment, the second biasing spring 214 can be a torsion spring having opposing legs that can be pressed together in compression and biased apart in tension. As shown in detail, the second biasing spring 214 can be disposed such that the spring axis coincides with the pivot axis of the second fulcrum 162. For example, the coil of the torsion spring 214 may slide over the pin or rivet of the second fulcrum 162 that is aligned and extends in the lateral direction 112.

One of the opposed spring legs 216 can contact and urge against the first lever arm 156. For example, when designed as a three-sided end channel 196, the first spring leg 216 can urge against the channel web 199 at a contact point offset from the second camming structure 192 with respect to the second fulcrum 162. To contact with the second spring leg 218, a lateral protrusion 219 can be included on the surface of the second beam end 159 of the elongated beam 152. The second torsion spring 214 is therefore constrained in contact between the channel web 199 of the second lever handle 156 and the lateral protrusion 219 of the second beam end 159 and can bias the second free end 190 apart from the elongated card beam 152.

To connect with the riser card bracket 150, the computer system 100 can include corresponding structures having appropriate catches that are located in the chassis volume 104. For example, as shown in FIG. 9, extending upwards from the planar expansion board 120 in the vertical direction 114 can be an upright post 220 having a first catch 222 formed at the distal end. The upright post 220 is therefore perpendicular to the horizontal plane 116 of the chassis 102. The upright post 220 can be located forwardly of the expansion socket slot 122 in the longitudinal direction 110 so as to be positioned adjacent to the front panel 106 of the chassis 102.

The first upright post 220 can be made of spring steel and the first catch 222 at the distal end can have a hook-like structure that is curved or bent to form an indentation in the longitudinal direction 110. When the riser card assembly 210 is aligned with the expansion socket slot 122, the forward card edge 144 may adjacently align with the upright post 220 in the longitudinal direction 110. Moreover, the height of the upright post 222 extending in the vertical direction 114 can be the same as the height of the expansion card 118 so that the first catch 222 is vertically proximate to the riser card bracket 150 extending along the upper card edge 140 of the expansion card.

An upright wall 224 can be associated with the fluid supply manifold 130 and can include a second catch 226 formed on the distal end that is vertically spaced above the manifold block 132. The second catch 226 can have a ledge-like structure including a shelf that is aligned in the longitudinal direction 110. The upright wall 224 and the ledge-like second catch 226 can also extend the lateral width of the manifold block 132 in the lateral direction 112. When the riser card assembly 210 is positioned above the expansion board 120 and the fluid ports 149 align with the manifold ports 134 in the longitudinal direction 110, the rearward card edge 146 can be moved into sliding contact with the upright wall 226. Moreover, the height of the upright wall 224 in the vertical direction 114 can correspond with the height of the expansion card 118 so that that the second catch 226 vertically aligns with the riser card bracket 150 extending along the upper card edge 140.

After aligning in the longitudinal direction the lower card edge 142 with the expansion board 120 and the fluid ports 149 with the manifold port 134, to plug in and install the expansion board 118 into the expansion socket slot 122, a vertically downward force, indicated by arrow 228, is applied to move the riser card assembly 210 downward in the vertical direction 114, as shown in FIG. 9. The vertical downward force 218 therefore inserts the conductive traces along the lower card edge 142 into forcible contact with the corresponding spring contacts of the expansion socket slot 122 and forcibly plugs the fluid ports 149 into fluid connection with the manifold ports 134 of the fluid manifold 130. The forward card edge 144 may also make sliding contact with the upright post 220 and the rearward card edge 146 may make sliding contact with the upright wall 224. Typically, the downward vertical force 228 is applied by hand during assembly of the computer system.

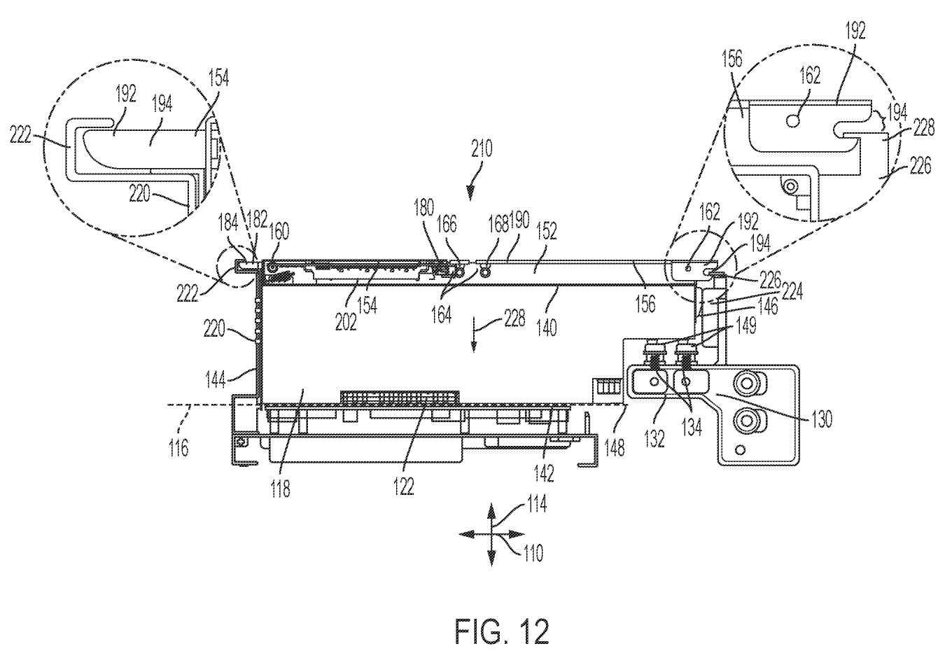

Mating engagement of the expansion card 118 with the expansion socket slot 122 of the expansion board 120 may require an elevated vertical force 228 in particular configurations including, for example, when establishing fluid tight connections between the fluid ports 149 and the manifold ports 134. To facilitate installation of the riser card assembly 210, the first and second lever handles 154, 156 can be actuated to forcibly engage with the corresponding structures within the chassis, such as the upright post 220 and the upright wall 224. For example, referring to FIG. 12, the first and second camming structures 182, 192 on the expansion card bracket 150 can positively engage with the first and second catches 222, 226 to increase and supplement the vertical downward force 228.

When the first beam end 158 vertically aligns with the first catch 222 at the distal end of the upright post 220 projecting in the vertical direction 114 above the expansion board 120, the camming prong 184 of the first camming structure 182 aligns with the hook-like configuration of the first catch 222. Pivotal articulation of the first lever handle 154 to rotate about the first fulcrum 160 causes the camming prong 184 to move and be received into the indentation created by the hook-like structure of the first catch 222.

Once the pivoting camming prong 184 engages in contact with the first catch 222, which is vertically fixed with respect to the vertical direction 114 by the upright post 220, further rotation of the camming prong 184 into parallel alignment with the longitudinal direction 110 causes a downward force in the vertical direction 114 to be applied at the first beam end 158 of the elongated card beam 152 extending over the upper card edge 140. Further pivoting movement of the first camming structure 182 thereafter causes downward displacement of the riser card bracket 150 and the expansion card 118 attached thereto.

Similarly, when the second beam end 159 vertically aligns with the second catch 226 formed as a ledge or shelf extending along the top of the upright wall 224, the camming jaw 194 associated with the second camming structure 192 is positioned vertically proximate, in the vertical direction 114, to the ledge-like second catch 226. Pressing the second free end 190 of the second lever handle 156 vertically downward to pivot about the second fulcrum 162 rotates the camming jaw 194 on the opposite end of the second lever handle 156 upwards to engage with second catch 226. For example, the ledge-like structure of the second catch 224 that projects laterally from the upright wall 224 can be received into the slots defined by the bifurcated camming jaws 194 during pivotal rotation of the second camming structure 192 with respect to the second fulcrum 162.

When the camming jaws 194 contact the ledge-like second catch 226, which is vertically fixed in position with respect to the vertical direction 114 by the upright wall 224, the further pivotal rotation of the second camming structure 192 results in a downward force being applied to the elongated card beam 152 attached across the upper card edge 140. Hence, further articulation of the second lever handle 156 applies a downward force to the riser card assembly 210 moving the assembly vertically toward the expansion board 120 in the vertical direction 114.

Pivoting the first lever handle 154 at the first fulcrum 160 creates and applies a mechanical advantage with respect to the interaction between the first camming structure 180 and the first catch 220. For example, the dimension between the first free end 180 and the first camming structure 182 with respect to the first fulcrum 160 produces a force multiplier that increases the vertically downward force applied between the first beam end 158 and the expansion card 118 proximate the forward card edge 144. The increased force is also transferred to and directed along the portion of lower card edge 142 that aligns with and that is pressed into insertion with the expansion socket slot 122 mounted on the expansion board 120.

Similarly, pivoting the second lever handle 156 at the second fulcrum 162 creates a mechanical advantage applied at the physical interaction between the second camming structure and the second catch 226. For example, the relative dimensions between the second free end 190 and the second camming structure 192 creates the multiplication of forces in the vertical direction 114 applied between the second beam end 159 and the riser card 118 at the second card edge 146. The increased vertical force may be particularly directed and applied to the fluid tight engagement between the manifold ports 134 and the fluid ports 149 along the recessed card edge 148.

The mechanical advantage created by the first and second lever handles 154, 156 enables forcible installation of the riser card assembly 210, and particularly between the lower card edge 142 and the expansion socket slot 122 and between the fluid ports 149 and the manifold ports 134, with relatively low input force. For example, the dimensions of the between the fulcrums 160, 162 and the free ends 180, 190 compared to the dimensions between the fulcrums and the camming structures 182, 192, can be configured to increases the input force that is applied at the point of application in accordance with the mechanical advantage provided by the lever rule. In an example, the downward vertical force 228 applied at the connection between the lower card edge and the expansion socket slot, and between the fluid port and the manifold ports, may be on the order of 10 kilograms. Further, amplifying and applying the increased forces simultaneously at both the first and second beam ends 158, 159 distributes the vertically directed forces more evenly across the upper card edges in the longitudinal direction 110. The simultaneously applied forces also results in uniform downward movement or displacement of the riser card assembly 210 with respect to the expansion board 120 preventing or correcting for misalignment.

When the first and second lever handles 154, 156 are pivoted adjacent to the elongated card beam 152 and parallel to the longitudinal direction 110, the first and second camming structures 184, 192 may full engage the respective first and second catches 222, 228. Moreover, the first camming prong 184 and the bifurcated camming jaws 194 and slot created there between may also be aligned with the longitudinal direction 110.

The force input at the first and second free ends 180, 190 to articulate the first and second lever 154, 156 with respect to the card beam 152 must be sufficient to overcome the biasing forces applied by the first and second biasing springs 212, 214. For example, because of the configuration of the first biasing spring 212 located between the first lever handle 154 and the second elongated card beam 152, and the configuration of the second biasing spring 214 between the second lever handle 156 and the elongated lever beam 152, the first and second free ends are typically biased apart from and upward of the elongated card beam 152. The forces applied to the first and second lever handles 154, 156 to cause pivotal rotation about the first and second fulcrums 160, 162 must been sufficient to overcome the biasing forces attributable to the first and second biasing springs 212, 214.

To prevent the first and second lever handles 154, 156 from unintentionally pivoting into the released arrangement due to the biasing forces attributable to the first and second biasing springs 212, 214, and thereby releasing the riser card assembly 210 with respect to the expansion board 120 and the liquid supply manifold 134, the locking mechanism associated with the pair of locking slots 164 and the first and second locking knobs 166, 168 can be engaged. For example, pivotally rotating the first and second free ends 180, 190 with respect to the first and second fulcrums 160, 162 moves the first and second locking knobs 166, 168 vertically downwards into sliding contact with the pair of locking slots 164. The sizes and dimensions between the locking slots 164 and the first and second locking knobs 166, 168 can result in a snap-fit engagement between the first and second free ends 180, 190 and the elongated card beam 154.

When the first lever handle 154 is locked in parallel alignment to the elongated card beam 152, the first biasing spring 212 embodied as a coil spring is stretched into tension by the spatial displacement between the spring hook 186 and the first beam end 158, which are moved apart by the pivotal rotation of the first lever handle 154 about the first fulcrum. Conversely, when the second lever handle 156 is locked in parallel alignment to the elongated card beam 152, the second biasing spring 214 embodied as a torsion spring is compressed. For example, the channel web 199 of the three sided end channel 196 located on the second lever handle 156 presses downwardly upon the first spring leg 216 and the second spring leg 218 is spatially constrained by the lateral protrusion 219 on the second beam end 159. Movement of those structures toward each other compresses the second basing spring.

Moreover, the snap-fit engagement between the locking slots 164 and the locking knobs 166, 168 can be sufficient to maintain the fixed engagement between the first and second camming structures 182, 192 and the first and second catches 222, 226. The vertical downward force 228 is maintained in the vertical direction 114 on the riser card assembly 210 resisting counter forces or unintended disengagement with the expansion card socket 122 and/or the manifold ports 134. To release the riser card assembly 210 from the expansion board 120 and/or the fluid supply manifold 130, the first and second free ends 180, 190 of the first and second lever handles 154, 156 are respectively moved vertically upward to disengage the locking knobs 166, 168 from the locking slots 164. The first and second biasing springs 212, 214 can pivotally swing the first and second free ends 180, 192 upwards with respect to the card beam 152, thereby pivotally moving and disengaging the first and second camming structures 182, 192 from the first and second catches 222, 226 respectively.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A riser card bracket for bracing an expansion card to an expansion board comprising:
a card beam elongated in a longitudinal direction between a first beam end and a second beam end, the card beam adapted to attach to an upper card edge of the expansion card;
a first lever handle pivotally joined to the card beam at a first fulcrum proximate the first beam end, the first lever handle including a first free end and a first camming structure oppositely located with respect to the first fulcrum, wherein the first camming structure is adapted to engage a first catch to displace the first beam end in a vertical direction orthogonal to the longitudinal direction;
a second lever handle pivotally joined to the card beam at a second fulcrum proximate the second beam end, the second lever handle including a second free end and a second camming structure oppositely located with respect to the second fulcrum, wherein the second camming structure is adapted to engage a second catch to displace the second beam end in the vertical direction orthogonal to the longitudinal direction.

2. The riser card bracket of claim 1, wherein the first camming structure includes a camming prong aligned along the first lever handle and adapted to be received in the first catch having a hook-like configuration.

3. The riser card bracket of claim 2, wherein the second camming structure includes camming jaws aligned along the second lever handle and adapted to receive the second catch having a ledge-like configuration.

4. The riser card bracket of claim 3, further comprising:
a first biasing spring disposed to bias apart the card beam and the first lever handle; and
a second biasing spring disposed to bias apart the card beam and the second lever handle.

5. The riser card bracket of claim 4, wherein the first biasing spring is a coil spring connected between the first beam end and the first lever handle and the second biasing spring is a torsion spring biased against the second beam end and the second lever handle.

6. The riser card bracket of claim 5, wherein the first camming structure includes a first spring hook to connect to the coil spring.

7. The riser card bracket of claim 6, wherein the second lever handle includes an end channel and the torsion spring abuts against a channel web of the end channel.

8. The riser card bracket of claim 3, wherein:
the first free end includes a first locking knob to lock the first handle lever to the card beam and oppose the first biasing spring; and
the second free end includes a second locking knob to lock the second handle lever to the card beam and oppose the second biasing spring.

9. The riser card bracket of claim 8, wherein the card beam includes a first locking slot and a second locking slot disposed therein and adapted to snap with the first locking knob and the second locking knob respectively.

10. The riser card bracket of claim 1, wherein the first beam end includes one or more fastener apertures adapted to receive fasteners for attaching the card beam to the riser card.

11. The riser card bracket of claim 1, wherein the second beam end includes an extension leg extending perpendicular to the longitudinal direction and having one or more fastener apertures therein adapted to receive fasteners for attaching the card beam to the riser card.

12. A method of installing an expansion card in a chassis for a computer system comprising:
attaching a riser card bracket to an upper card edge of the expansion card such that a card beam of the riser card bracket extends longitudinally along the upper card edge;
aligning a lower card edge of the expansion card over an expansion socket slot on an expansion board;
aligning a fluid port on the expansion card with a manifold port on a fluid supply manifold;
forcibly inserting the lower card edge into the expansion socket slot by pivoting a first lever handle about a first fulcrum with respect to the card beam to engage a first camming structure on the first lever handle with a first catch fixedly located in the server chassis; and
forcibly connecting the fluid port with the manifold port by pivoting a second lever handle with respect to the card beam about a second fulcrum to engage a second camming structure of the second lever handle with a second catch fixedly located in the server chassis.

13. The method of claim 12, wherein the step of pivoting the first lever handle includes forcibly contacting a camming prong of the first camming structure with the first catch having a hook-like structure.

14. The method of claim 13, wherein the step of pivoting the second lever handle includes forcibly contacting camming jaws of the second camming structure with the second catch having a ledge-like structure.

15. The method of claim 12, further comprising locking the first lever handle in parallel alignment with the card beam and locking the second lever handle in parallel alignment with the card beam.

16. The method of claim 12, further comprising:
biasing apart the card beam and the first lever handle when unlocked with a first biasing spring; and
biasing apart the card beam and the second lever handle when unlocked with a second biasing spring.

17. The method of claim 12, wherein the step of attaching the riser card bracket to the expansion card includes:
attaching a first beam end of the card beam to a forward card edge of the expansion card with one or more fasteners; and
attaching a second beam end of the card beam to a rearward card edge of the expansion card with one or more fasteners.

18. The method of claim 12, wherein engaging the second camming structure with the second catch generates approximately 10 kilogram or more of force to forcibly connect the fluid port with the manifold port.

19. A computer system comprising:
an expansion board having a expansion socket slot and located in a horizontal plane aligned in a chassis, the expansion card further including an upright post extending in a vertical direction orthogonal to the horizontal plane and having a first catch at a distal end thereof;
a fluid supply manifold located in the horizontal plane and having one or more manifold port oriented in the vertical direction;
a riser card assembly including:
an expansion card having an upper card edge orientable in a longitudinal direction, a lower card edge insertable in an expansion socket slot, and one or more fluid ports orientable in the vertical direction; and
a riser card bracket having:
a card beam attached along the upper card edge,
a first lever handle pivotally joined to the card beam at a first fulcrum, the first lever handle with a first free end and camming structure adapted to engage the first catch on upright post; and
a second lever handle pivotally joined to the card beam at a second fulcrum, the second lever handle with second free end and a second camming structure adapted to engage the second catch on the fluid supply manifold.

20. The computer system of claim 19, wherein the riser card bracket has a first biasing spring situated to bias apart the card beam and the first lever handle and a second biasing spring situated to bias apart the card beam and the second lever handle.
